(19) United States
(12) Patent Application Publication
(10) Pub. No.: US 2019/0296260 A1
(43) Pub. Date: Sep. 26, 2019

(54) DISPLAY PANEL AND METHOD FOR MAKING THE SAME

(71) Applicant: Wuhan China Star Optoelectronics Semiconductor Display Technology Co., Ltd., Wuhan (CN)

(72) Inventor: Shuang LI, Shenzhen (CN)

(21) Appl. No.: 16/153,121

(22) Filed: Oct. 5, 2018

Related U.S. Application Data
(63) Continuation of application No. PCT/CN2018/089006, filed on May 30, 2018.

(30) Foreign Application Priority Data
Mar. 20, 2018 (CN) 201810229056.2

(51) Int. Cl. H01L 51/52; H01L 51/00; H01L 51/56

(52) U.S. Cl. CPC H01L 51/5253; H01L 2227/323; H01L 51/56; H01L 51/0097

(57) ABSTRACT

Provided is a method for making a display panel, comprising: making a flexible protective layer on a rigid substrate; forming a flexible substrate on the flexible protective layer; making a light-emitting device on the flexible substrate; forming an encapsulation structure on the light-emitting device to encapsulate the light-emitting device on the flexible substrate; separating the rigid substrate from the flexible protective layer so that the flexible protective layer, the flexible substrate, the light-emitting device and the encapsulation structure collectively form a display panel. A display panel is also provided. The subject matter provided may avoid the flexible substrate from being damaged in a process of lifting-off from the rigid substrate, thereby improving the reliability of the display panel.

### RELATED APPLICATION

This application is a continuation application of PCT Patent Application No. PCT/CN2018/089006 filed on May 30, 2018, which claims the priority benefit of Chinese Patent Application No. 201810229056.2, filed on Mar. 20, 2018, which is herein incorporated by reference in its entirety.

### FIELD OF THE INVENTION

The present disclosure relates to the field of display technique, and more particularly to display panel and method for making the same.

### BACKGROUND OF THE INVENTION

An organic light-emitting diode (OLED) has the advantages of fast response, wide temperature range, self-illumination, flexible display, etc. OLED is known as third-generation display technology after cathode-ray tube (CRT), liquid crystal display (LCD)/light-emitting diode (LED). With the increasing market demand, the OLED technique has been extensively applied in the display field.

Compared with an OLED display panel of a conventional rigid substrate, OLED display panel of a flexible substrate has the advantages of such as being portable and bendable, and has attracted more and more attention. At present, a flexible substrate of the OLED display panel is made on a rigid substrate, in which the flexible substrate may then be lifted-off from the rigid substrate by a lift-off process to form a flexible display panel. Polyimide film (PI) is commonly employed in the making of flexible substrate of the OLED display panel. However, the process of making the polyimide film tends to generate bubbles or introduce foreign matter, so that the flexible substrate will not completely be lifted-off from the rigid substrate in the lift-off process, resulting in perforation and peeling of the flexible substrate. These problems not only damage the film layer of the flexible substrate, but also result in an abnormal encapsulation structure of the light-emitting device. Furthermore, it is easier for moisture and oxygen in the air to intrude into the light-emitting device through the damaged position of the flexible substrate, thus causing display failure.

### SUMMARY OF THE INVENTION

The present disclosure provides a display panel and a method for making the same, which can prevent the flexible substrate from being damaged when being lifted-off from the rigid substrate, thereby improving the reliability of the display panel.

In one aspect, the disclosure provides a method for making a display panel, comprising:
making a flexible protective layer on a rigid substrate;
forming a flexible substrate on the flexible protective layer;
making a light-emitting device on the flexible substrate;
forming an encapsulation structure on the light-emitting device to encapsulate the light-emitting device on the flexible substrate;
separating the rigid substrate from the flexible protective layer so that the flexible protective layer, the flexible substrate, the light-emitting device and the encapsulation structure collectively form a display panel.

In some instances, the process of making a flexible protective layer on a rigid substrate may comprise making a polyimide film on the rigid substrate.

In such instances, the process of making a flexible protective layer on a rigid substrate may further comprise making a barrier film on the polyimide film, wherein the barrier film is used to block moisture and oxygen from intruding into the light-emitting device.

Further, the process of making the barrier film on the polyimide film may comprise:
making one or more of first barrier walls on the polyimide film;
making a first inorganic layer on the polyimide film, the first inorganic layer covering at least one of the first barrier walls;
making a first organic layer on the first inorganic layer, at least one of the first barrier walls surrounding the first organic layer;
making a second inorganic layer on the first organic layer, the second inorganic layer covering the first organic layer and at least one of the first barrier walls.

In some instances, the projection area of the flexible substrate onto the plane of the flexible protective layer is within the flexible protective layer.

In some instances, the material of the first barrier wall is one or more of compounds selected from the group consisting of epoxy resin, polyimide, polymethyl methacrylate, and organosilicone.

In certain instances, the first barrier wall described herein may comprise water-absorbing particles.

The thickness of the first inorganic layer described herein may be in a range of 100 nm to 2 μm.

In some instances, the material of the first inorganic layer is one or more of compounds selected from the group consisting of zirconium aluminate, graphene, aluminum oxide, zirconium oxide, zinc oxide, silicon nitride, silicon carbonitride, silicon oxide, titanium oxide, and diamond-like carbon.

In some instances, the process of making a light-emitting device on the flexible substrate may comprise:
making a thin film transistor array on the flexible substrate;
making one or more of second barrier walls on the thin film transistor array;
making an organic light-emitting layer on the thin film transistor array, at least one of the second barrier walls surrounding the organic light-emitting layer, the thin film transistor array and the organic light-emitting layer forming a light-emitting device.

In some instances, the process of forming an encapsulation structure on the light-emitting device may comprise:
making a third inorganic layer on the organic light-emitting layer, the third inorganic layer covering the organic light-emitting layer and at least one of the second barrier walls;
making a second organic layer on the third inorganic layer, at least one of the second barrier walls surrounding the second organic layer;
making a fourth inorganic layer on the second organic layer, the fourth inorganic layer covering the second organic layer and at least one of the second barrier walls.

In another aspect, the disclosure provides a display panel, wherein the display panel comprises a flexible protective layer, a flexible substrate disposed on the flexible protective layer, a light-emitting device disposed on the flexible substrate, and an encapsulation structure for encapsulating the light-emitting device.

In some instances, the flexible protective layer comprises a polyimide film and a barrier film disposed on the polyimide film, and the flexible substrate is disposed on the barrier film.

The barrier film may comprise one or more of first barrier walls disposed on the polyimide film, one or more of first inorganic layers covering at least one of the first barrier walls, one or more of first organic layers surrounded by at least one of the first barrier walls, and one or more of second inorganic layers covering the first organic layer and at least one of the first barrier walls.

The light-emitting device described herein may comprise a thin film transistor array and an organic light-emitting layer disposed on the thin film transistor array, and the thin film transistor array is disposed on the flexible substrate.

The encapsulation structure described herein may comprise at least one of second barrier walls, and at least one of the second barrier walls surrounds the organic light-emitting layer.

The encapsulation structure described herein may further comprise a third inorganic layer covering the second barrier wall, a second organic layer surrounded by the second barrier wall, and a fourth inorganic layer covering the second organic layer and the second barrier wall.

The disclosure provides a display panel and a method for making the same, in which a flexible protective layer, a flexible substrate, a light-emitting device, and an encapsulation structure are sequentially made on a rigid substrate. In the process of separating the rigid substrate from the flexible substrate, due to the existence of the flexible protective layer disposed between the rigid substrate and the flexible substrate, the flexible substrate is not subjected to adhesion to the rigid substrate during the lifting-off process, so that the flexible substrate will not be destroyed. Accordingly, the process of lifting-off the rigid substrate does not affect the light-emitting device. Furthermore, the flexible protective layer may also prevent moisture and oxygen from entering the light-emitting device, thereby improving the ability of the display panel to block moisture and oxygen.

### BRIEF DESCRIPTION OF THE DRAWINGS

In order to illustrate the prior art or the implementation of the present disclosure more clearly, the following drawings which are to be used in the description of the implementation will be briefly described. It will be understood that the drawings are in accordance with some implementations of the present disclosure, and other drawings may be obtained by the skilled in the art without the creative work.

FIG. 1 is a flow chart of a method for making a display panel in accordance with an implementation of the present disclosure.

FIG. 2 is a schematic diagram of step S100 of the method for making a display panel provided by the present disclosure.

FIG. 3 is a schematic diagram of step S200 of the method for making a display panel provided by the present disclosure.

FIG. 4 is a schematic diagram of step S300 of the method for making a display panel provided by the present disclosure.

FIG. 5 is a schematic diagram of step S400 of the method for making a display panel provided by the present disclosure.

FIG. 6 is a schematic diagram of step S500 of the method for making a display panel provided by the present disclosure.

FIG. 7 is a schematic diagram of a display panel in accordance with an implementation of the present disclosure.

### DETAILED DESCRIPTION OF THE INVENTION

Various objects, features and advantages of the present disclosure will become more apparent from the following detailed description accompanied with the drawings and implementations. It should be noted that the implementations or the features thereof of the present disclosure may be combined with each other without conflict.

The following description is provided to clearly and completely explain the exemplary implementations of the disclosure. It is apparent that the following implementations are merely some of the disclosure rather than all of the disclosure. According to the implementations disclosed herein, all the other implementations attained by those skilled in the art without creative endeavor are within the protection scope of the disclosure.

In addition, the following description of various implementations is provided to illustrate specific examples that may be used to implement the present disclosure with reference to accompanying drawings. In the description, terms of orientation such as “top”, “bottom”, “upper”, “lower”, “front”, “back”, “left”, “right”, “inside”, “outside” should be construed to refer to the orientation as described or as shown in the drawings. Such terms of orientation are not the limitations to the present disclosure, as the terms are used merely for convenience of explaining the present disclosure rather than for specifically or implicitly indicating a particular orientation or a particular construction or a particular operation of a device or an element.

In the process of making flexible OLED display device, a flexible substrate of the OLED display panel may be first made on a rigid substrate, and then a light-emitting device may be made on the flexible substrate, followed by encapsulating the light-emitting device and then lifting-off the flexible substrate from the rigid substrate by a lift-off process to form a flexible display panel. Polyimide film (PI) is commonly employed in the making of flexible substrate of the OLED display panel. However, the process of making the polyimide film tends to generate bubbles or introduce foreign matter, so that the flexible substrate will not completely be lifted-off from the rigid substrate in the lift-off process, resulting in perforation and peeling of the flexible substrate. These problems not only damage the film layer of the flexible substrate, but also result in an abnormal encapsulation structure of the light-emitting device. Furthermore, it is easier for moisture and oxygen in the air to intrude into the light-emitting device through the damaged position of the flexible substrate, thus causing display failure.

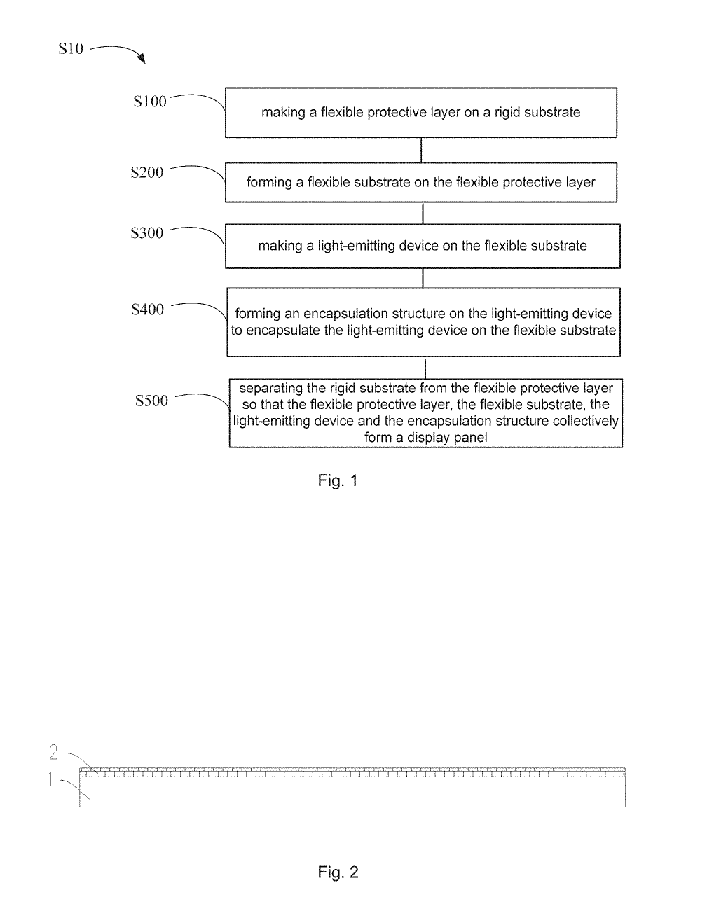

Referring to FIG. 1, a method S10 for making a display panel, such as a flexible OLED display device, is shown in accordance with the present disclosure. The method S10 for making a display panel comprises the following steps:
S100: making a flexible protective layer on a rigid substrate;
S200: forming a flexible substrate on the flexible protective layer;
S300: making a light-emitting device on the flexible substrate;
S400: forming an encapsulation structure on the light-emitting device to encapsulate the light-emitting device on the flexible substrate;
S500: separating the rigid substrate from the flexible protective layer so that the flexible protective layer, the flexible substrate, the light-emitting device and the encapsulation structure collectively form a display panel.

In such implementation, a flexible protective layer, a flexible substrate, a light-emitting device, and an encapsulation structure are sequentially made on a rigid substrate. In the process of separating the rigid substrate from the flexible substrate, due to the existence of the flexible protective layer disposed between the rigid substrate and the flexible substrate, the flexible substrate is not subjected to adhesion to the rigid substrate during the lifting-off process, so that the flexible substrate will not be destroyed. Accordingly, the process of lifting-off the rigid substrate does not affect the light-emitting device. Furthermore, the flexible protective layer may also prevent moisture and oxygen from entering the light-emitting device, thereby improving the ability of the display panel to block moisture and oxygen.

The steps of the above implementation will be described in detail below with reference to the accompanying drawings.

At S100, as shown in FIG. 2, rigid substrate 1 is a glass substrate where flexible protective layer 2 is made thereon. In some other implementations, rigid substrate 1 may include metal substrate, ceramic substrate, plastic substrate and composite substrate. It can be understood that rigid substrate 1 has a plane for carrying display panel 100. The plane is where flexible protective layer 2 is disposed on and where the fabrication process of the display panel 100 is performed.

Flexible protective layer 2 is a slightly bendable film which may fit and be lifted-off from the rigid substrate 1.

In one implementation, as shown in FIG. 2, flexible protective layer 2 is a polyimide film. At S100, organic material is coated onto rigid substrate 1 to form an organic thin film, which may then be heated and cured to form a polyimide film. The fabrication process of each layer of the display panel 100 is then performed on the polyimide film.

In such implementation, the polyimide film may be used as a protective layer of flexible substrate. When attempting to separate from the functional layers of the display panel 100, the rigid substrate 1 may be lifted-off from the polyimide film, thus achieving the separation between the rigid substrate 1 and the functional layers. According to the present disclosure, polyimide film rather than flexible substrate 3 is subjected to the adhesion to the rigid substrate 1. Flexible substrate 3 may be protected from being damaged, even when the polyimide film is not completely lifted-off from rigid substrate 1 and is perforated or torn or peeled, thereby ensuring the integrity of flexible substrate 3 and ensuring that light-emitting device 4 encapsulated by flexible substrate 3 is not attacked by moisture and oxygen.

In other implementations, the flexible protective layer 2 may also comprise other flexible layers. The flexible protective layer 2 may be a film layer formed by mixing polyimide with other substances, such as a film layer formed by mixing polyimide with a substance that absorbs moisture and oxygen, or a film layer formed by mixing polyimide and a binder, or a film layer formed by laminating polyimide and a release layer.

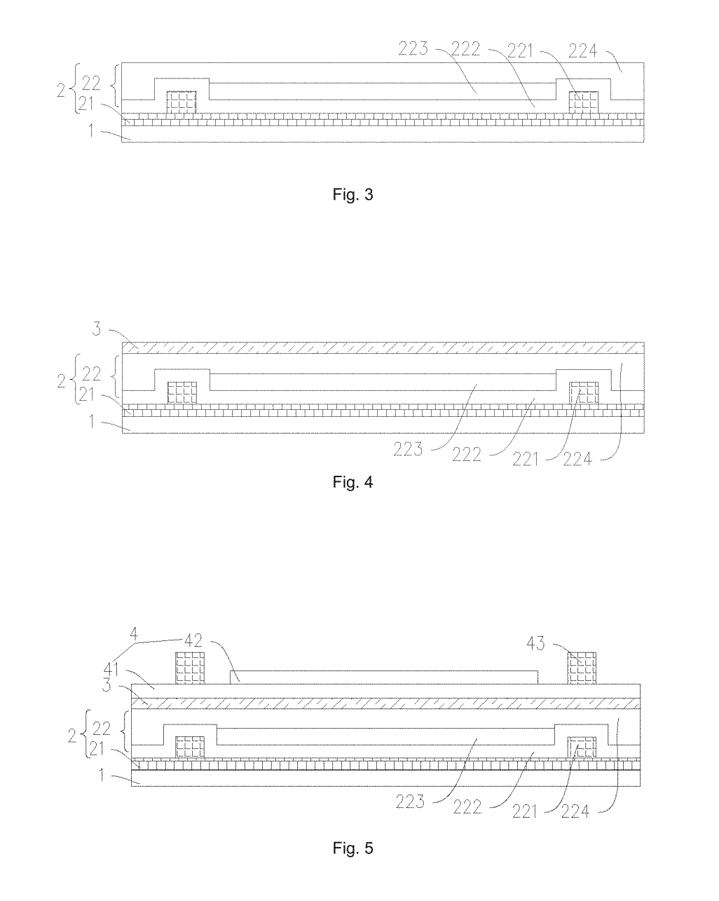

In another implementation, as shown in FIG. 3, the flexible protective layer 21 comprises a polyimide film 21 and a barrier film 22 fitting the polyimide film 21. At S100, organic material is coated onto rigid substrate 1 to form an organic thin film, which may then be heated and cured to form a polyimide film 21. An inorganic film layer and an organic film layer are formed on the polyimide film 21 in an alternating pattern. The inorganic film layer and the organic film layer which are disposed in an alternating pattern form a barrier film 22 for blocking the moisture and oxygen. Due to the weak performance of the polyimide film 21 in blocking moisture and oxygen, a barrier film 22, which is able to prevent moisture and oxygen intruding into the light-emitting device 4 through it, is used to enhance the ability of the flexible protective layer 2 to block moisture and oxygen, thus improving the reliability of the display panel 100.

Barrier film 22 includes one or more of first barrier walls, and includes alternating inorganic layer and organic layer disposed on one or more of the first barrier walls. The process of forming the barrier film 22 on the polyimide film may include the following steps.

At S101, one or more of the first barrier walls 221 are formed on the polyimide film.

Each of the first barrier walls 221 has homocentric squares, and the first barrier wall 221 may define a boundary of the first organic layer 223 to avoid the problem that the first organic layer 223 may not be shaped and may flow anywhere. Specifically, the first barrier wall 221 may be rectangular or circular.

In such implementation, when a plurality of the first barrier walls 221 having different sizes are included, the large first barrier wall 221 surrounds the small first barrier wall 221. The area surrounded by the first barrier wall 221 is defined as the area surrounded by the innermost first barrier wall 221. The area surrounded by the first barrier wall 221 is opposite to the light-emitting device 4, and the orthographic projection of the light-emitting device 4 onto the plane of the first barrier wall 221 is within the area surrounded by the first barrier wall 221 to facilitate the ability of the display area of display panel 100 to bend.

The first barrier wall 221 may be made by a process of dispensing or inkjet printing. The process of the first barrier wall 221 is simple, and the production cost can be effectively reduced.

The number of the first barrier wall 221 is not limited. One or three or five first barrier walls 221 may be included, for instance.

The material of the first barrier wall 221 includes but not limits to one or more of epoxy resin, polyimide, polymethyl methacrylate, and organosilicone. A preferred material of the first barrier wall 221 may be high-temperature resistant polyimide having improved properties, which has resistance to high temperature and strong adhesion to the polyimide film 21.

In one implementation, the material of the first barrier wall 221 further includes adhesive and water-absorbing particles. The water-absorbing particles are mixed in the adhesive. When moisture and oxygen intrude into the display panel 100, the first barrier wall 221 absorbs the intrusive moisture and oxygen, preventing the moisture and oxygen from intruding further into the light-emitting device 4.

Optionally, the material of the adhesive includes one or more of epoxy resin, polyimide, polymethyl methacrylate, organosilicone, and a combination thereof. The water-absorbing particles may be capable of absorbing water, and in the form of nanoparticles having a particle diameter in a range of from several nanometers to tens of nanometers. The material of the water-absorbing particles may be CaO (calcium oxide) or SrO (strontium oxide) or a mixture thereof.

At S102, first inorganic layer 222 is formed on the polyimide film, wherein first inorganic layer 222 covers the first barrier wall 221 and the area surrounded by the first barrier wall 221. First inorganic layer 222 is an inorganic film for encapsulating, and first inorganic layer 222 covers at least one first barrier wall 221. First inorganic layer 222 fits to the surface of the polyimide film 21 and the outer peripheral surface of the first barrier wall 221 which is covered. The first inorganic layer 222 is used to block and prevent moisture and oxygen from intruding into the light-emitting device 4.

Optionally, the first inorganic layer 222 may be deposited by processes such as atomic layer deposition (ALD), pulsed laser deposition (PLD), sputtering, plasma enhanced chemical vapor deposition (PECVD). The thickness of the first inorganic layer 222 may be in a range of 100 nm to 2 μm. The first inorganic layer 222 is made of a water-proof or water-absorbing material of high relative density, including but not limited to ZrAlₓO_{y} (zirconium aluminate), graphene, Al₂O₃ (alumina), ZrO₂ (zirconia), ZnO₂. (zinc oxide), SiNₓ (silicon nitride), SiCN (silicon carbonitride), SiOx (silicon oxides), TiO₂ (titanium oxide), DLC (diamond-like carbon), and the like.

At S103, first organic layer 223 is formed on first inorganic layer 222, wherein at least one of the first barrier walls 221 surrounds the first organic layer 223. The edge of the first organic layer 223 does not extend beyond the outermost first barrier wall 221. The first organic layer 223 is used for buffering the stress during the bending of display panel 100, and for adding and coating some particulate contaminants to prevent the particulate contaminants from piercing the inorganic layer, thereby avoiding degrading the performance of the flexible protective layer 2 in blocking moisture and oxygen.

Optionally, the first organic layer 223 may be coated by adopting processes such as IJP (inkjet printing), PECVD (plasma enhanced chemical vapor deposition), slot coating, spin-coating or dispensing. The first organic layer 223 may have a thickness of 1-20 μm. The material of the first organic layer 223 includes, but is not limited to, one or more of acrylic acid, hexamethyldisiloxane, polyacrylate, polycarbonate, polystyrene, and a combination thereof, for buffering the stress during a bending or a folding of display panel 100 and for covering particulate contaminants.

At S104, the second inorganic layer 224 is made on the first organic layer 223, wherein the second inorganic layer 224 covers the first organic layer 223 and at least one of the first barrier walls 221. The second inorganic layer 224 is an inorganic film for encapsulating, and the second inorganic layer 224 covers at least one first barrier wall 221. The second inorganic layer 224 fits the surface of the first organic layer 223. The second inorganic layer 224 is used to further block moisture and oxygen in the air. The second inorganic layer 224 and the first inorganic layer 222 form two protective walls for blocking and preventing moisture and oxygen from intruding further into the light-emitting device 4.

Optionally, the second inorganic layer 224 may be deposited by processes such as atomic layer deposition (ALD), pulsed laser deposition (PLD), sputtering, plasma enhanced chemical vapor deposition (PECVD). The thickness of the second inorganic layer 224 may be in a range of 100 nm to 2 μm. The second inorganic layer 224 is made of a water-proof or water-absorbing material of high relative density, including but not limited to ZrAlₓO_{y} (zirconium aluminate), graphene, Al₂O₃ (alumina), ZrO₂ (zirconia), ZnO₂. (zinc oxide), SiNₓ (silicon nitride), SiCN (silicon carbonitride), SiOx (silicon oxides), TiO₂ (titanium oxide), DLC (diamond-like carbon), and the like.

In other implementations, flexible protective layer 2 comprises a polyimide film and comprises an inorganic layer or an organic layer which are formed on the polyimide film in an alternating pattern. The number of the inorganic layer and the organic layer is not specifically limited.

At S200, referring to FIG. 4, flexible substrate 3 is formed on flexible protective layer 2. The material of flexible substrate 3 may be polyimide.

Further, projection area of the flexible substrate 3 onto the plane of the flexible protective layer 2 is within the flexible protective layer 2. The flexible substrate 3 completely fits the surface of the flexible protective layer 2, and the flexible substrate 3 does not fit the rigid substrate 1, In the process of phase separation of the flexible substrate 3 from the rigid substrate 1, the flexible substrate 3 is not damaged by the adhesion to rigid substrate 1.

At S300, referring to FIG. 5, light-emitting device 4 is made on flexible substrate 3, which may include the following steps.

Referring to FIG. 5, thin film transistor array 41 is made on the flexible substrate 3.

Referring to FIG. 5, one or more second barrier walls 43 are formed on thin film transistor array 41.

Organic light-emitting layer 42 is formed on thin film transistor array 41, wherein at least one of the second barrier walls 43 surrounds the organic light-emitting layer 42. The thin film transistor array 41 and the organic light-emitting layer 42 form a light-emitting device 4. The light-emitting device 5 is encapsulated on the flexible substrate 3.

Referring to FIG. 5, one or more second barrier walls 43 are formed on the flexible substrate 3 by dispensing or inkjet printing. Each of the second barrier walls 43 has homocentric squares, and the second barrier wall 43 surrounds the light-emitting device 4. Specifically, the second barrier wall 43 may be rectangular or circular.

In such implementation, when a plurality of the second barrier walls 43 having different sizes are included, the large second barrier walls 43 surrounds the small second barrier walls 43. The area surrounded by second barrier walls 43 is defined as the area surrounded by the innermost second barrier walls 43. The area surrounded by second barrier walls 43 is opposite to the light-emitting device 4, and the orthographic projection of the light-emitting device 4 onto the plane of second barrier walls 43 is within the area surrounded by second barrier walls 43 to facilitate the ability of the display area of display panel 100 to bend.

The number of second barrier wall 43 is not limited. One or three or five second barrier walls 43 may be included, for instance.

The material of second barrier wall 43 includes but not limits to one or more of epoxy resin, polyimide, polymethyl methacrylate, and organosilicone. A preferred material of second barrier wall 43 may be high-temperature resistant polyimide having improved properties, which has resistance to high temperature and strong adhesion to the flexible substrate 3.

In one implementation, the material of second barrier wall 43 further includes adhesive and water-absorbing particles. The water-absorbing particles are mixed in the adhesive. When moisture and oxygen intrude into the display panel 100, second barrier wall 43 absorbs the intrusive moisture and oxygen, preventing the moisture and oxygen from intruding further into the light-emitting device 4.

Optionally, the material of the adhesive includes one or more of epoxy resin, polyimide, polymethyl methacrylate, organosilicone, and a combination thereof. The water-absorbing particles may be capable of absorbing water, and in the form of nanoparticles having a particle diameter in a range of from several nanometers to tens of nanometers. The material of the water-absorbing particles may be CaO (calcium oxide) or SrO (strontium oxide) or a mixture thereof.

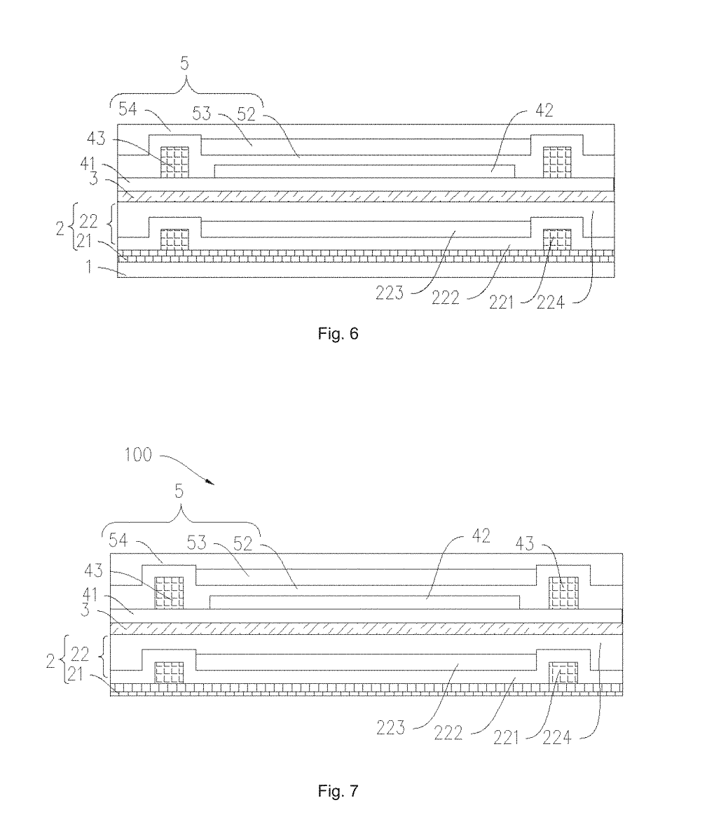

At S400, referring to FIG. 6, an encapsulation structure 5 is formed on the light-emitting device 4. The encapsulation structure 5 includes third inorganic layer 52, second organic layer 53, and fourth inorganic layer 54. Fabricating the encapsulation structure 5 on the light-emitting device 4 may include the following steps.

At S401, referring to FIG. 6, third inorganic layer 52 is formed on the organic light-emitting layer 42, wherein third inorganic layer 52 covers organic light-emitting layer 42 and at least one of the second barrier walls 43. The third inorganic layer 52, at least one of the second barrier walls 43 and the flexible substrate 3 are used to encapsulate the light-emitting device 4. The third inorganic layer 52 is used to prevent moisture and oxygen from intruding into the light-emitting device 4 through the encapsulate structure.

Optionally, third inorganic layer 52 may be deposited by processes such as atomic layer deposition (ALD), pulsed laser deposition (PLD), sputtering, plasma enhanced chemical vapor deposition (PECVD). The thickness of third inorganic layer 52 may be in a range of 100 nm to 2 μm. Third inorganic layer 52 is made of a water-proof or water-absorbing material of high relative density, including but not limited to ZrAlₓO_{y} (zirconium aluminate), graphene, Al₂O₃ (alumina), ZrO₂ (zirconia), ZnO₂. (zinc oxide), SiNₓ (silicon nitride), SiCN (silicon carbonitride), SiOx (silicon oxides), TiO₂ (titanium oxide), DLC (diamond-like carbon), and the like.

At S402, referring to FIG. 6, second organic layer 53 is formed on third inorganic layer 52, wherein second barrier wall 43 surrounds second organic layer 53. The edge of second organic layer 53 does not extend beyond the outermost second barrier wall 43. Second organic layer 53 is used for buffering the stress during a bending of the display panel 100, and for adding and coating some particulate contaminants to prevent the particulate contaminants from piercing the inorganic layer, thereby avoiding degrading the performance of the flexible protective layer 2 in blocking moisture and oxygen.

Second barrier wall 43 may define a boundary of the second organic layer 53 to avoid the problem that the second organic layer 53 may not be shaped and may flow anywhere.

Optionally, second organic layer 53 may be coated by adopting processes such as IJP (inkjet printing), PECVD (plasma enhanced chemical vapor deposition), slot coating, spin-coating or dispensing. Second organic layer 53 may have a thickness of 1-20 μm. The material of second organic layer 53 includes, but is not limited to, one or more of acrylic acid, hexamethyldisiloxane, polyacrylate, polycarbonate, polystyrene, and a combination thereof, for buffering the stress during a bending or a folding of display panel 100 and for covering particulate contaminants.

At S403, referring to FIG. 6, fourth inorganic layer 54 is made on second organic layer 53, wherein fourth inorganic layer 54 covers second organic layer 53 and at least one of second barrier walls 43. Fourth inorganic layer 54 covers at least one second barrier wall 43. Fourth inorganic layer 54 fits the surface of second organic layer 53 and the surface of third inorganic layer 52. Fourth inorganic layer 54 is used to further block moisture and oxygen in the air. Fourth inorganic layer 54 and third inorganic layer 52 form two protective walls for blocking and preventing moisture and oxygen from intruding further into the light-emitting device 4.

Optionally, fourth inorganic layer 54 may be deposited by processes such as atomic layer deposition (ALD), pulsed laser deposition (PLD), sputtering, plasma enhanced chemical vapor deposition (PECVD). The thickness of fourth inorganic layer 54 may be in a range of 100 nm to 2 μm. Fourth inorganic layer 54 is made of a water-proof or water-absorbing material of high relative density, including but not limited to ZrAlₓO_{y} (zirconium aluminate), graphene, Al₂O₃ (alumina), ZrO₂ (zirconia), ZnO₂. (zinc oxide), SiNₓ (silicon nitride), SiCN (silicon carbonitride), SiOx (silicon oxides), TiO₂ (titanium oxide), DLC (diamond-like carbon), and the like.

In other implementations, encapsulation structure 5 comprises an inorganic layer or an organic layer in an alternating pattern. The number of the inorganic layer and the organic layer is not specifically limited.

At S500, referring to FIG. 7, rigid substrate 1 is separated from the flexible protective layer 2 so that the flexible protective layer 2, the flexible substrate 3, and the light-emitting device 4 collectively form display panel 100. Rigid substrate 1 may be lifted-off from the flexible protective layer 2 by a laser beam.

In such implementation, the process of lifting-off flexible protective layer 2 from rigid substrate 1 may cause defects, such as perforations or grooves, in flexible protective layer 2 due to the adhesion to rigid substrate 1. The defects, such as perforations or grooves, in the flexible protective layer 2 are filled up to make the flexible protective layer 2 planar, facilitating the application of the display panel 100 in the display device.

The flexible protective layer 2, flexible substrate 3, light-emitting device 4 and encapsulation structure are sequentially disposed on rigid substrate 1. In the process of separating the rigid substrate 1 from the flexible substrate 3, due to the existence of the flexible protective layer 2 disposed between the rigid substrate and the flexible substrate, the flexible substrate 3 is not subjected to adhesion to rigid substrate 1 during the lifting-off process, so that the flexible substrate 3 will not be destroyed. Accordingly, the process of lifting-off the rigid substrate 1 does not affect the light-emitting device 4. Furthermore, the flexible protective layer 2 may also prevent moisture and oxygen from entering the light-emitting device 4, thereby improving the ability of the display panel 100 to block moisture and oxygen.

Referring to FIG. 7, the present disclosure further provides display panel 100 made by the method for making display panel 100 described above. The display panel 100 includes flexible protective layer 2, flexible substrate 3 disposed on flexible protective layer 2, light-emitting device 4 disposed on flexible substrate 3, and an encapsulation structure 5 for encapsulating the light-emitting device 4. The encapsulation structure 5 and flexible substrate 3 are used to encapsulate light-emitting device 4 to prevent the light-emitting device 4 from being corroded by moisture and oxygen. The flexible protective layer 2 is used in the fabrication process of the display panel 100, in which the separation of display panel 100 from the rigid substrate 1 is achieved by separating the rigid substrate 1 from flexible protective layer 2, thus ensuring the integrity of the flexible substrate 3.

In one implementation, flexible protective layer 2 is a polyimide film, and the polyimide film fits flexible substrate 3 for protecting the flexible substrate 3. In the process of lifting-off display panel 100 from rigid substrate 1, flexible protective layer 2 can ensure the integrity of flexible substrate 3, thereby protecting the light-emitting device 4 and improving the reliability of display panel 100.

In one implementation, referring to FIG. 7, flexible protective layer 2 comprises polyimide film 21 and barrier film 22 disposed on the polyimide film 21. Flexible substrate 3 is disposed on barrier film 22. In the process of lifting-off display panel 100 from rigid substrate 1, polyimide film 21 can ensure the integrity of flexible substrate 3, thereby preventing moisture and oxygen from intruding into light-emitting device 4 and improving the reliability of display panel 100.

In an implementation, barrier film 22 includes one or more of first barrier walls 221, first inorganic layer 222, first organic layer 223, and second inorganic layer 224. At least one of first barrier walls 221 is disposed on the polyimide film. First inorganic layer 222 covers at least one of first barrier walls 221. At least one of the first barrier walls 221 surrounds the first organic layer 223. Second inorganic layer 224 covers first organic layer 223 and at least one of the first barrier walls 221. For specific description of such implementation, reference may be made to step S100, and details are not described herein again.

In one implementation, light-emitting device 4 includes thin film transistor array 41 disposed on flexible substrate 3 and includes organic light-emitting layer 42 formed on thin film transistor array 41, The encapsulation structure 5 includes at least one second barrier wall 43, wherein one or more of second barrier walls 43 are formed on thin film transistor array 41, and wherein at least one second barrier wall 43 surrounds organic light-emitting layer 42.

In an implementation, encapsulation structure 5 includes third inorganic layer 52, second organic layer 53, and fourth inorganic layer 54. Third inorganic layer 52 covers second barrier wall 43. Second barrier wall 43 surrounds second organic layer 53. Fourth inorganic layer 54 covers second organic layer 53 and second barrier wall 43. For specific description of such implementation, reference may be made to step S400, and details are not described herein again.

It is apparent to those skilled in the art that the present application is not limited to the details of the above exemplary embodiments, and the present application can be implemented in other specific forms without departing from the spirit or essential characteristics of the application. Therefore, the present embodiments are to be considered as illustrative and not restrictive, and the scope of the invention is defined by the appended claims instead of the above description. All changes in the same meaning and within the same scope of equivalent elements recited in the claims are included in this application. Any reference signs in the claims should not be construed as limitations of the claims. In addition, it should be understood that the term “comprising/including” does not exclude other elements or steps.

It should be noted that the above implementations are only used to explain the technical solutions of the present application, and are not limited thereto. Although the present application is described in detail with reference to the preferred embodiments, those skilled in the art should understand that the modifications or equivalent substitutions of the present application are not intended to be excluded from the scope of the invention.

What is claimed is:

1. A method for making a display panel, comprising:
making a flexible protective layer on a rigid substrate;
forming a flexible substrate on the flexible protective layer;
making a light-emitting device on the flexible substrate;
forming an encapsulation structure on the light-emitting device to encapsulate the light-emitting device on the flexible substrate;
separating the rigid substrate from the flexible protective layer so that the flexible protective layer, the flexible substrate, the light-emitting device and the encapsulation structure collectively form a display panel.

2. The method for making a display panel according to claim 1, wherein process of making a flexible protective layer on a rigid substrate comprises making a polyimide film on the rigid substrate.

3. The method for making a display panel according to claim 2, wherein process of making a flexible protective layer on a rigid substrate further comprises making a barrier film on the polyimide film, and wherein the barrier film is used to prevent moisture and oxygen from entering the light-emitting device.

4. The method for making a display panel according to claim 3, wherein process of making the barrier film on the polyimide film comprises:
making one or more of first barrier walls on the polyimide film;
making a first inorganic layer on the polyimide film, the first inorganic layer covering at least one of the first barrier walls;
making a first organic layer on the first inorganic layer, at least one of the first barrier walls surrounding the first organic layer;
making a second inorganic layer on the first organic layer, the second inorganic layer covering the first organic layer and at least one of the first barrier walls.

5. The method for making a display panel according to claim 4, wherein projection area of the flexible substrate onto the plane of the flexible protective layer is within the flexible protective layer.

6. The method for making a display panel according to claim 4, wherein material of the first barrier wall is one or more of compounds selected from the group consisting of epoxy resin, polyimide, polymethyl methacrylate, and organosilicone.

7. The method for making a display panel according to claim 4, wherein the first barrier wall comprises water-absorbing particles.

8. The method for making a display panel according to claim 4, wherein the first inorganic layer has a thickness of 100 nm to 2 μm.

9. The method for making a display panel according to claim 4, wherein material of the first inorganic layer is one or more of compounds selected from the group consisting of zirconium aluminate, graphene, aluminum oxide, zirconium oxide, zinc oxide, silicon nitride, silicon carbonitride, silicon oxide, titanium oxide, and diamond-like carbon.

10. The method for making a display panel according to claim 1, wherein process of making a light-emitting device on the flexible substrate comprises:
making a thin film transistor array on the flexible substrate;
making one or more of second barrier walls on the thin film transistor array;
making an organic light-emitting layer on the thin film transistor array, at least one of the second barrier walls surrounding the organic light-emitting layer, the thin film transistor array and the organic light-emitting layer forming a light-emitting device.

11. The method for making a display panel according to claim 10, wherein process of forming an encapsulation structure on the light-emitting device comprises:
making a third inorganic layer on the organic light-emitting layer, the third inorganic layer covering the organic light-emitting layer and at least one of the second barrier walls;
making a second organic layer on the third inorganic layer, at least one of the second barrier walls surrounding the second organic layer;
making a fourth inorganic layer on the second organic layer, the fourth inorganic layer covering the second organic layer and at least one of the second barrier walls.

12. A display panel, wherein the display panel comprises a flexible protective layer, a flexible substrate disposed on the flexible protective layer, a light-emitting device disposed on the flexible substrate, and an encapsulation structure for encapsulating the light-emitting device.

13. The display panel according to claim 12, wherein the flexible protective layer comprises a polyimide film and a barrier film disposed on the polyimide film, and wherein the flexible substrate is disposed on the barrier film.

14. The display panel according to claim 13, wherein the barrier film may comprise one or more of first barrier walls disposed on the polyimide film, one or more of first inorganic layers covering at least one of the first barrier walls, one or more of first organic layers surrounded by at least one of the first barrier walls, and one or more of second inorganic layers covering the first organic layer and at least one of the first barrier walls.

15. The display panel according to claim 12, wherein the light-emitting device comprises a thin film transistor array and an organic light-emitting layer disposed on the thin film transistor array, the thin film transistor array being disposed on the flexible substrate.

16. The display panel according to claim 15, wherein the encapsulation structure comprises at least one of second barrier walls surrounding the organic light-emitting layer.

17. The display panel according to claim 16, wherein the encapsulation structure further comprises a third inorganic layer covering the second barrier wall, a second organic layer surrounded by the second barrier wall, and a fourth inorganic layer covering the second organic layer and the second barrier wall.
